(19) United States
(12) Patent Application Publication
(10) Pub. No.: US 2025/0226361 A1
(43) Pub. Date: Jul. 10, 2025

(54) SEMICONDUCTOR PACKAGE

(71) Applicant: SAMSUNG ELECTRONICS CO., LTD., Suwon-si (KR)

(72) Inventors: DAWOON JUNG, Suwon-si (KR); Haseob SEONG, Suwon-si (KR)

(73) Assignee: SAMSUNG ELECTRONICS CO., LTD., Suwon-si (KR)

(21) Appl. No.: 18/771,036

(22) Filed: Jul. 12, 2024

(30) Foreign Application Priority Data
Jan. 8, 2024 (KR) 10-2024-0002739

(51) Int. Cl. H01L 25/065; H01L 23/00; H01L 23/31; H01L 23/522

(52) U.S. Cl. CPC H01L 25/0657; H01L 23/5226; H01L 24/08; H01L 24/80; H01L 23/3107; H01L 24/05; H01L 2224/05557; H01L 2224/08146; H01L 2224/80375; H01L 2225/06568

(57) ABSTRACT

Provided is a semiconductor package including a lower semiconductor chip including a top surface and a bottom surface that are opposite to each other, an upper semiconductor chip on the top surface of the lower semiconductor chip and including a bottom surface and a top surface that are opposite to each other, a dielectric layer between the top surface of the lower semiconductor chip and the bottom surface of the upper semiconductor chip, a lower dielectric layer between the dielectric layer and the bottom surface of the upper semiconductor chip, an upper dielectric layer on the top surface of the upper semiconductor chip, and a connection structure that penetrates the dielectric layer and the lower dielectric layer, the connection structure being connected to the lower semiconductor chip and the upper semiconductor chip, wherein a width of the bottom surface of the upper semiconductor chip is greater than a width of the upper dielectric layer in a first direction, and wherein the first direction is parallel to the top surface of the lower semiconductor chip.

### CROSS-REFERENCE TO RELATED APPLICATION

This U.S. nonprovisional application claims priority to Korean Patent Application No. 10-2024-0002739 filed on Jan. 8, 2024 in the Korean Intellectual Property Office, the disclosure of which is hereby incorporated by reference in its entirety.

### BACKGROUND

### 1. Field

Embodiments of the present disclosure relate to a semiconductor package and a method of fabricating the same, and more particularly, to a stacked semiconductor package in which a plurality of semiconductor chips are stacked on a substrate and a method of fabricating the same.

### 2. Description of Related Art

In response to the rapid development of the electronic industry and user demands, electronic products have become smaller and increasingly multifunctional. There are also increased needs for miniaturization and multi-functionality of semiconductor devices used for electronic products. Accordingly, there has been proposed a semiconductor package in which a plurality of semiconductor chips having through electrodes are stacked in a vertical direction.

### SUMMARY

One or more embodiments provide a semiconductor package with improved durability and reliability.

According to an aspect of one or more embodiments, there is provided a semiconductor package including a lower semiconductor chip including a top surface and a bottom surface that are opposite to each other, an upper semiconductor chip on the top surface of the lower semiconductor chip and including a bottom surface and a top surface that are opposite to each other, a dielectric layer between the top surface of the lower semiconductor chip and the bottom surface of the upper semiconductor chip, a lower dielectric layer between the dielectric layer and the bottom surface of the upper semiconductor chip, an upper dielectric layer on the top surface of the upper semiconductor chip, and a connection structure that penetrates the dielectric layer and the lower dielectric layer, the connection structure being connected to the lower semiconductor chip and the upper semiconductor chip, wherein a width of the bottom surface of the upper semiconductor chip is greater than a width of the upper dielectric layer in a first direction, and wherein the first direction is parallel to the top surface of the lower semiconductor chip.

According to another aspect of one or more embodiments, there is provided a semiconductor package, including a lower semiconductor chip including a top surface and a bottom surface that are opposite to each other, a plurality of upper semiconductor chips on the top surface of the lower semiconductor chip and stacked in a direction perpendicular to the top surface of the lower semiconductor chip, the plurality of upper semiconductor chips including a first upper semiconductor chip and a second upper semiconductor chip adjacent to each other, a lower dielectric layer between the first upper semiconductor chip and the second upper semiconductor chip, an upper dielectric layer between the lower dielectric layer and the first upper semiconductor chip, and a connection structure that penetrates the upper dielectric layer and the lower dielectric layer, the connection structure being connected to the first upper semiconductor chip and the second upper semiconductor chip, wherein a width of the upper dielectric layer is less than a width of the lower dielectric layer in a first direction, and wherein the first direction is parallel to the top surface of the lower semiconductor chip.

According to still another aspect of one or more embodiments, there is provided a semiconductor package, including a lower semiconductor chip including a top surface and a bottom surface that are opposite to each other, an upper semiconductor chip on the top surface of the lower semiconductor chip and having a bottom surface and a top surface that are opposite to each other, a dielectric layer between the top surface of the lower semiconductor chip and the bottom surface of the upper semiconductor chip, a lower dielectric layer between the dielectric layer and the bottom surface of the upper semiconductor chip, an upper dielectric layer on the top surface of the upper semiconductor chip, and a connection structure that penetrates the dielectric layer and the lower dielectric layer, the connection structure being connected to the lower semiconductor chip and the upper semiconductor chip, wherein a lateral surface of the upper dielectric layer is rounded, wherein a width of the upper dielectric layer in a first direction decreases as a distance from the lower semiconductor chip along a direction perpendicular to the top surface of the lower semiconductor chip increases, and wherein the first direction is parallel to the top surface of the lower semiconductor chip.

### BRIEF DESCRIPTION OF DRAWINGS

Embodiments will be more clearly understood from the following detailed description taken in conjunction with the accompanying drawings in which:

FIG. 1 illustrates a cross-sectional view showing a semiconductor package according to one or more embodiments;

FIG. 2 illustrates an enlarged view showing section B of FIG. 1.

FIG. 3 illustrates an enlarged view showing section A of FIG. 1.

FIGS. 4 and 6 illustrate cross-sectional views showing a method of fabricating a semiconductor package according to one or more embodiments;

FIG. 5 illustrates an enlarged cross-sectional view of section A depicted in FIG. 4, showing a method of fabricating a semiconductor package according to one or more embodiments;

FIG. 7 illustrates a cross-sectional view showing a semiconductor package according to one or more embodiments;

FIGS. 8 and 9 illustrate cross-sectional views showing a method of fabricating a semiconductor package according to one or more embodiments; and

FIG. 10 illustrates a cross-sectional view showing a semiconductor package according to one or more embodiments.

### DETAILED DESCRIPTION

Hereinafter, embodiments are described in detail with reference to the attached drawings. The same reference numerals are used for the same components in the drawings, and the descriptions already given for the components are omitted.

Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

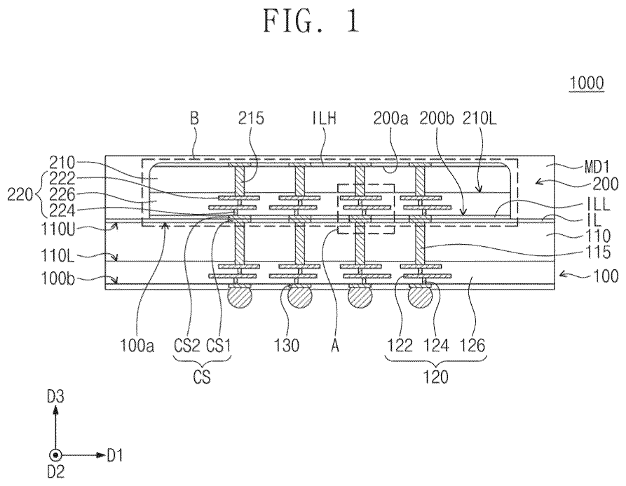

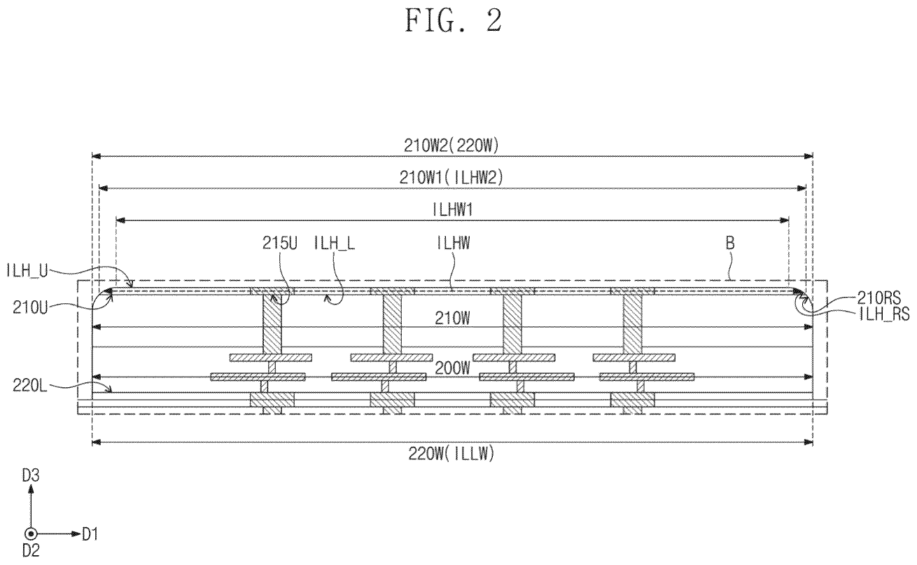

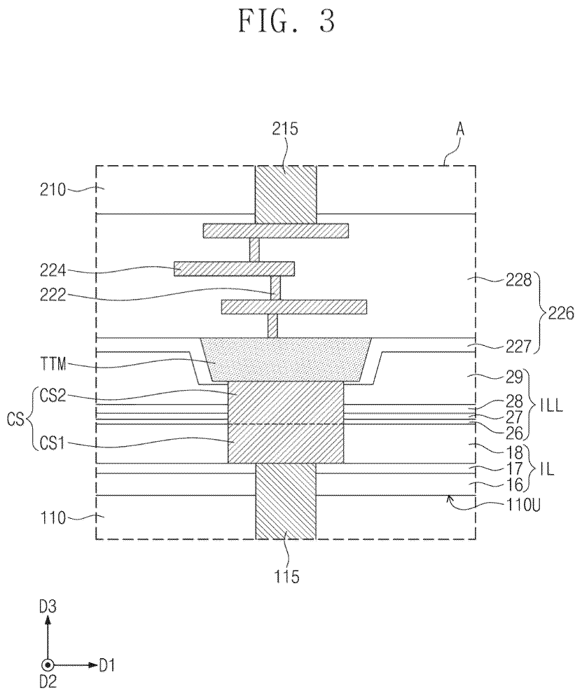

FIG. 1 illustrates a cross-sectional view showing a semiconductor package according to one or more embodiments. FIG. 2 illustrates an enlarged view showing section B of FIG. 1. FIG. 3 illustrates an enlarged view showing section A of FIG. 1.

Referring to FIG. 1, a semiconductor package 1000 may include a lower semiconductor chip 100, an upper semiconductor chip 200 on the lower semiconductor chip 100, a dielectric layer IL between the lower semiconductor chip 100 and the upper semiconductor chip 200, a lower dielectric layer ILL between the dielectric layer IL and the upper semiconductor chip 200, and a connection structure CS that penetrates the dielectric layer IL and the lower dielectric layer ILL to come into connection with the lower semiconductor chip 100 and the upper semiconductor chip 200.

The lower semiconductor chip 100 may include a lower semiconductor substrate 110, a lower circuit layer 120 on a bottom surface 110L of the lower semiconductor substrate 110, and a plurality of lower through vias 115 that penetrate the lower semiconductor substrate 110. The lower semiconductor substrate 110 may include a semiconductor material, such as, for example, silicon, germanium, or silicon-germanium.

The lower circuit layer 120 may include lower wiring patterns 122 and 124 and a lower wiring dielectric layer 126 that may be provided on and cover the lower wiring patterns 122 and 124. The lower wiring patterns 122 and 124 may include line patterns 122 and via patterns 124 connected to the line patterns 122. The lower circuit layer 120 may further include integrated circuits disposed on the bottom surface 110L of the lower semiconductor substrate 110, and the lower wiring patterns 122 and 124 may be electrically connected to the integrated circuits. The lower wiring patterns 122 and 124 may include metal, such as, for example, copper, aluminum, titanium, or tungsten, and the lower wiring dielectric layer 126 may include a silicon-containing dielectric material, such as, for example, one or more of silicon oxide, silicon nitride, silicon oxynitride, and tetraethylorthosilicate.

Each of the lower through vias 115 may penetrate the lower semiconductor substrate 110 to come into connection with a corresponding one (e.g., the line pattern 122) of the lower wiring patterns 122 and 124. The lower through vias 115 may include metal, such as, for example, copper (Cu).

The lower semiconductor chip 100 may have a top surface 100a and a bottom surface 100b that are opposite to each other. The top surface 100a of the lower semiconductor chip 100 may correspond to a top surface 110U of the lower semiconductor substrate 110, and a lower surface of the lower circuit layer 120 may be provided on and adjacent to the bottom surface 100b of the lower semiconductor chip 100. According to other one or more embodiments, the lower semiconductor chip 100 may be configured such that the lower circuit layer 120 may be provided on and adjacent to the top surface 100a and that the lower semiconductor substrate 110 may be provided on and adjacent to the bottom surface 100b. For example, the lower circuit layer 120 may be provided between the dielectric layer IL and the lower semiconductor substrate 100. The lower semiconductor chip 100 may be, for example, a memory chip, a logic chip, an application processor (AP) chip, or a system-on-chip (SOC).

Lower chip pads 130 may be disposed on the bottom surface 100b of the lower semiconductor chip 100. Each of the lower chip pads 130 may be connected to a corresponding one (e.g., the via pattern 124) of the lower wiring patterns 122 and 124 in the lower circuit layer 120. The lower chip pads 130 may include a different material from that of the lower wiring patterns 122 and 124. For example, the lower chip pads 130 may include metal, such as, for example, aluminum.

Referring to FIGS. 1 to 3, the upper semiconductor chip 200 may include an upper semiconductor substrate 210, an upper circuit layer 220 on a bottom surface 210L of the upper semiconductor substrate 210, and a plurality of upper through vias 215 that penetrate the upper semiconductor substrate 210. The upper semiconductor substrate 210 may include a semiconductor material, such as, for example, silicon, germanium, or silicon-germanium. The upper semiconductor substrate 210 may have a rounded lateral surface 210RS. A width 210W1 in a first direction D1 of a top surface 210U of the upper semiconductor substrate 210 may be less than a width 210W2 in the first direction D1 of the bottom surface 210L of the upper semiconductor substrate 210. A width 210W in the first direction D1 of the upper semiconductor substrate 210 may decrease in a direction (e.g., a third direction D3) away from and perpendicular to the top surface 100a of the lower semiconductor chip 100 toward the top surface 210U. A width 210W1 in the first direction D1 of the top surface 210U of the upper semiconductor substrate 210 may be a minimum width in the first direction D1 of the upper semiconductor substrate 210. The width 210W2 in the first direction D1 of the bottom surface 210L of the upper semiconductor substrate 210 may be a maximum width in the first direction D1 of the upper semiconductor substrate 210. The first direction D1 may be parallel to the top surface 100a of the lower semiconductor chip 100.

The upper circuit layer 220 may include upper wiring patterns 222 and 224 and an upper wiring dielectric layer 226 that may be provided on and cover the upper wiring patterns 222 and 224. The upper wiring patterns 222 and 224 may include line patterns 222 and via patterns 224 connected to the line patterns 222. The upper circuit layer 220 may further include integrated circuits disposed on the bottom surface 210L of the upper semiconductor substrate 210, and the upper wiring patterns 222 and 224 may be electrically connected to the integrated circuits. The upper wiring patterns 222 and 224 may include metal, such as, for example, copper, aluminum, titanium, or tungsten. The upper wiring dielectric layer 226 may include a first interlayer dielectric layer 227 and a second interlayer dielectric layer 228 that are sequentially stacked. A subsidiary pattern TTM may be disposed on the first interlayer dielectric layer 227. The subsidiary pattern TTM may include, for example, aluminum. The second interlayer dielectric layer 228 may be provided on and cover the upper wiring patterns 222 and 224. The first and second interlayer dielectric layers 227 and 228 may include a silicon-containing dielectric material, such as, for example, one or more of silicon oxide, silicon nitride, silicon oxynitride, and tetraethylorthosilicate.

A width 220W in the first direction D1 of the upper circuit layer 220 may be greater than the width 210W1 in the first direction D1 of the top surface 210U of the upper semiconductor substrate 210. The width 220W in the first direction D1 of the upper circuit layer 220 may be the same as the maximum width in the first direction D1 of the upper semiconductor substrate 210. For example, a width 200W in the first direction D1 of the upper semiconductor chip 200 may decrease with increasing distance from the lower semiconductor chip 100 along the direction (e.g., the third direction D3) perpendicular to the top surface 100a of the lower semiconductor chip 100.

Each of the upper through vias 215 may penetrate the upper semiconductor substrate 210 to be connected with a corresponding one of the upper wiring patterns 222 and 224 in the upper circuit layer 220. For example, the upper through vias 215 may contact a corresponding one of the upper wiring patterns 222 and 224. The upper through vias 215 may include metal, such as, for example, copper (Cu).

The upper semiconductor chip 200 may have a top surface 200a and a bottom surface 200b that are opposite to each other. The upper semiconductor substrate 210 may be provided on and adjacent to the top surface 200a of the upper semiconductor chip 200, and the upper circuit layer 220 may be provided on and adjacent to the bottom surface 200b of the upper semiconductor chip 200. The upper semiconductor chip 200 may be a memory chip, a logic chip, an application processor (AP) chip, or a system-on-chip (SOC).

An upper dielectric layer ILH may be disposed on the top surface 200a of the upper semiconductor chip 200 and on the upper semiconductor substrate 210. The upper dielectric layer ILH may have a rounded lateral surface ILH_RS. A width ILHW1 in the first direction D1 of a top surface ILH_U of the upper dielectric layer ILH may be less than a width ILHW2 in the first direction D1 of a bottom surface ILH_L of the upper dielectric layer ILH. A width ILHW in the first direction D1 of the upper dielectric layer ILH may decrease with increasing distance from the lower semiconductor chip 100 along the direction (e.g., the third direction D3) perpendicular to the top surface 100a of the lower semiconductor chip 100. The width ILHW1 in the first direction D1 of the top surface ILH_U of the upper dielectric layer ILH may be a minimum one of widths in the first direction D1 of the upper dielectric layer ILH. The width ILHW2 in the first direction D1 of the bottom surface ILH_U of the upper dielectric layer ILH may be a maximum one of widths in the first direction D1 of the upper dielectric layer ILH. The maximum width ILHW2 in the first direction D1 of the upper dielectric layer ILH may be the same as the minimum width 210W1 in the first direction D1 of the upper semiconductor substrate 210.

The lower dielectric layer ILL may be disposed on a bottom surface 220L of the upper circuit layer 220 of the upper semiconductor chip 200. A width ILLW in the first direction D1 of the lower dielectric layer ILL may be greater than the maximum width ILHW2 in the first direction D1 of the upper dielectric layer ILH. The width ILLW in the first direction D1 of the lower dielectric layer ILL may be the same as the maximum width 210W2 in the first direction D1 of the upper semiconductor substrate 210.

The connection structure CS may include a first connection part CS1 in the dielectric layer IL and a second connection part CS2 in the lower dielectric layer ILL. The connection structure CS may include a conductive material. The first connection part CS1 and the second connection part CS2 may include the same conductive material. For example, the first connection part CS1 and the second connection part CS2 may include the same metal (e.g., copper).

The dielectric layer IL may be provided on and cover a lateral surface of the first connection part CS1 and the lower semiconductor chip 100 (e.g., the top surface 110U of the lower semiconductor substrate 110). The dielectric layer IL may include a first upper passivation layer 16, a second upper passivation layer 17, and a third upper passivation layer 18 that are sequentially stacked. The first upper passivation layer 16 may be provided on and cover the top surface 110U of the lower semiconductor substrate 110. The dielectric layer IL may have a single-layered or multi-layered structure of at least one selected from silicon oxide, silicon nitride, and silicon carbonitride.

The lower dielectric layer ILL may be provided on and cover the second connection part CS2 and the bottom surface 200b of the upper semiconductor chip 200 (e.g., the bottom surface 220L of the upper circuit layer 220). The lower dielectric layer ILL may include a first lower passivation layer 26, a second lower passivation layer 27, a third lower passivation layer 28, and a fourth lower passivation layer 29 that are sequentially stacked. The first, second, third, and fourth lower passivation layers 26, 27, 28, and 29 may include at least one selected from, for example, silicon oxide, silicon nitride, and silicon carbonitride, and may have a single-layered or multi-layered structure.

The dielectric layer IL on the top surface 100a of the lower semiconductor chip 100 may be in direct contact with the lower dielectric layer ILL on the bottom surface 200b of the upper semiconductor chip 200, and the first connection part CS1 may be in direct contact with the second connection part CS2. The lower semiconductor chip 100 and the upper semiconductor chip 200 may be directly bonded or hybrid copper bonded to each other through the direct contact mentioned above.

A first mold layer MD1 may be disposed on the top surface 100a of the lower semiconductor chip 100, and may be provided on and cover the upper semiconductor chip 200. The first mold layer MD1 may include a dielectric resin, for example, an epoxy molding compound (EMC). The first mold layer MD1 may further include fillers, and the fillers may be dispersed in the dielectric resin. The fillers may include, for example, silicon oxide (SiO₂).

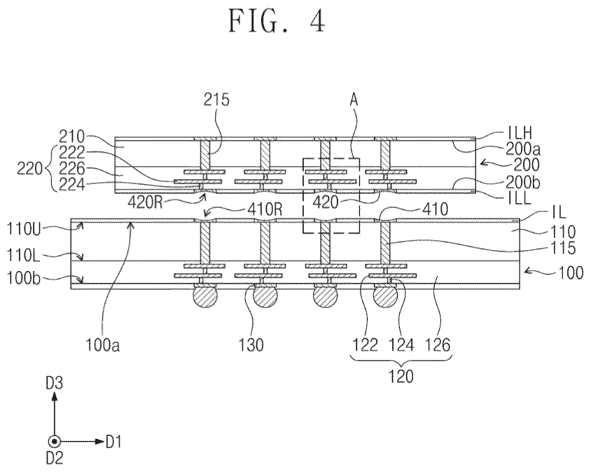

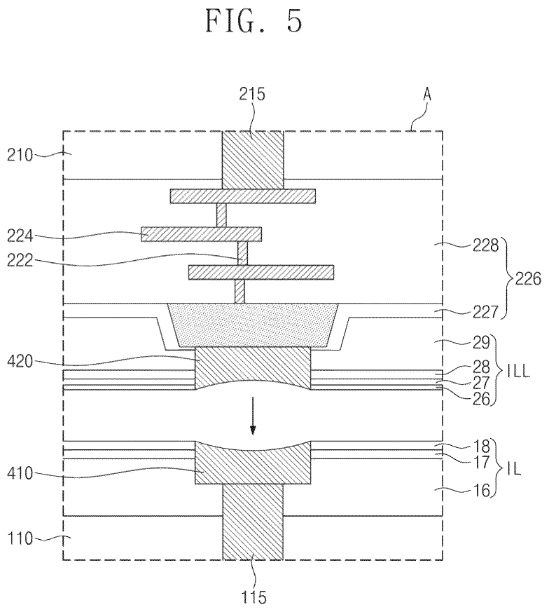

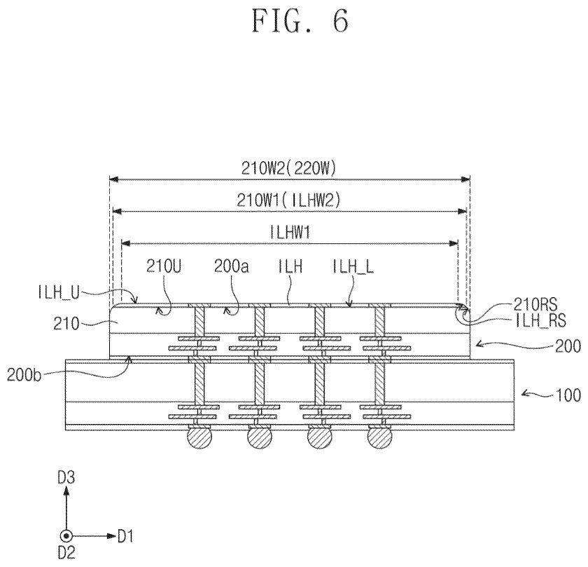

FIGS. 4 and 6 illustrate cross-sectional views showing a method of fabricating a semiconductor package according to one or more other embodiments. FIG. 5 illustrates an enlarged cross-sectional view of section A depicted in FIG. 4, showing a method of fabricating a semiconductor package according to one or more other embodiments. The same explanation as that of the semiconductor package discussed with reference to FIGS. 1 to 3 will be omitted for brevity of description.

Referring to FIGS. 4 and 5, a lower semiconductor chip 100 may be provided. The lower semiconductor chip 100 may include a lower semiconductor substrate 110, a lower circuit layer 120 on a bottom surface 110L of the lower semiconductor substrate 110, and a plurality of lower through vias 115 that penetrate the lower semiconductor substrate 110. The lower circuit layer 120 may include lower wiring patterns 122 and 124 and a lower wiring dielectric layer 126 that may be provided on and cover the lower wiring patterns 122 and 124. Each of the lower through vias 115 may penetrate the lower semiconductor substrate 110 and may be connected with a corresponding one of the lower wiring patterns 122 and 124 in the lower circuit layer 120. For example, each of the lower through vias 115 may contact one of the lower wiring patterns 122 and 124.

The lower semiconductor chip 100 may have a top surface 100a and a bottom surface 100b that are opposite to each other. The top surface 100a of the lower semiconductor chip 100 may correspond to a top surface 110U of the lower semiconductor substrate 110, and the lower circuit layer 120 may be provided on and adjacent to the bottom surface 100b of the lower semiconductor chip 100. Lower chip pads 130 may be formed on the bottom surface 100b of the lower semiconductor chip 100. Each of the lower chip pads 130 may be connected to a corresponding one 124 of the lower wiring patterns 122 and 124 in the lower circuit layer 120.

A dielectric layer IL may be formed on the top surface 100a of the lower semiconductor chip 100 and on the lower semiconductor substrate 110. For example, first, second, and third upper passivation layers 16, 17, and 18 may be sequentially formed on the lower semiconductor substrate 110. The first upper passivation layer 16 and the second upper passivation layer 17 may be provided on and cover lateral surfaces of the lower through vias 115. The third upper passivation layer 18 may be formed on the second upper passivation layer 17.

First connection pads 410 may be formed on the top surface 100a of the lower semiconductor chip 100. Each of the first connection pads 410 may be connected to a corresponding one of the lower through vias 115. The first connection pads 410 may include metal (e.g., copper). The formation of the first connection pad 410 may include, for example, forming a connection pad mask pattern on the dielectric layer IL, using the connection pad mask pattern as an etch mask to etch the first, second, and third upper passivation layers 16, 17, and 18, and filling the etched portion with a conductive material. The first connection pads 410 may be formed to each have a recess 410R that is inwardly recessed toward the upper semiconductor chip 200. Lateral surfaces of the first connection pads 410 may be covered with the second and third upper passivation layers 17 and 18, and the recesses 410R of the first connection pads 410 may be recessed.

An upper semiconductor chip 200 may be provided. The upper semiconductor chip 200 may include an upper semiconductor substrate 210 and an upper circuit layer 220. The upper circuit layer 220 may include upper wiring patterns 222 and 224 and an upper wiring dielectric layer 226 that may be provided on and cover the upper wiring patterns 222 and 224. The upper semiconductor chip 200 may have a top surface 200a and a bottom surface 200b that are opposite to each other. The upper circuit layer 220 may be provided on and adjacent to the bottom surface 200b of the upper semiconductor chip 200. A lower dielectric layer ILL may be formed on the bottom surface 200b of the upper semiconductor chip 200, and may be formed to be provided on and cover the upper circuit layer 220. An upper dielectric layer ILH may be formed on the upper semiconductor substrate 210 of the upper semiconductor chip 200, and may be formed to be provided on and cover the top surface 200a of the upper semiconductor chip 200.

Second connection pads 420 may be formed on the bottom surface 200b of the upper semiconductor chip 200. Each of the second connection pads 420 may be connected to a corresponding one 224 of the upper wiring patterns 222 and 224 in the upper circuit layer 220. The second connection pads 420 may include metal (e.g., copper), and may be formed by a fabrication method substantially the same as that used for forming the first connection pads 410. The first and second connection pads 410 and 420 may include the same metallic material. The second connection pads 420 may be formed to each have a recess 420R that is inwardly recessed toward the lower semiconductor chip 100. The lower dielectric layer ILL may be provided on and cover a lateral surface of the second connection pad 420, and may expose the recess 420R of each of the second connection pads 420.

Referring to FIGS. 4, 5, and 6, the upper semiconductor chip 200 may be provided on the top surface 100a of the lower semiconductor chip 100. The bottom surface 200b of the upper semiconductor chip 200 may face the top surface 100a of the lower semiconductor chip 100. The upper semiconductor chip 200 may be stacked to enable the bottom surface 200b of the upper semiconductor chip 200 to face the top surface 100a of the lower semiconductor chip 100. The first connection pad 410 of the lower semiconductor chip 100 may face the second connection pad 420 of the upper semiconductor chip 200. The dielectric layer IL and the lower dielectric layer ILL may face and directly contact each other. An annealing process may be performed after the upper semiconductor chip 200 is stacked on the lower semiconductor chip 100. The annealing process may allow diffusion of metallic elements (e.g., copper) in the first and second connection pads 410 and 420, and may cause thermal expansion of the first and second connection pads 410 and 420. Therefore, the recesses 420R of the second connection pads 420 may be filled with the first and second connection pads 410 and 420. The annealing process may cause that the first and second connection pads 410 and 420 are directly bonded to each other or in contact with each other with no boundary. The first and second connection pads 410 and 420 may be directly bonded to form a single structure, which single unitary piece may be a connection structure CS. The dielectric layer IL and the lower dielectric layer ILL may be directly bonded by the annealing process.

A planarization process may be performed to planarize a top surface ILH_U of the upper dielectric layer ILH. The planarization process may allow the upper dielectric layer ILH and the upper semiconductor substrate 210 to have rounded lateral surfaces ILH_RS and 210RS, respectively. A width 210W1 in a first direction D1 of a top surface 210U of the upper semiconductor substrate 210 may be less than a width 210W2 in the first direction D1 of a bottom surface 210L of the upper semiconductor substrate 210. A width 210W in the first direction D1 of the upper semiconductor substrate 210 may decrease with increasing distance from the lower semiconductor chip 100 along a direction (e.g., a third direction D3) perpendicular to the top surface 100a of the lower semiconductor chip 100. The width 210W1 in the first direction D1 of the top surface 210U of the upper semiconductor substrate 210 may be a minimum width in the first direction D1 of the upper semiconductor substrate 210. The width 210W2 in the first direction D1 of the bottom surface 210L of the upper semiconductor substrate 210 may be a maximum width in the first direction D1 of the upper semiconductor substrate 210.

A width ILHW1 in the first direction D1 of the top surface ILH_U of the upper dielectric layer ILH may be less than a width ILHW2 in the first direction D1 of a bottom surface ILH_L of the upper dielectric layer ILH. A width ILHW in the first direction D1 of the upper dielectric layer ILH may decrease in the direction (e.g., the third direction D3) away from and perpendicular to the top surface 100a of the lower semiconductor chip 100 toward the top surface ILH_U. The width ILHW1 in the first direction D1 of the top surface ILH_U of the upper dielectric layer ILH may be a minimum one of widths in the first direction D1 of the upper dielectric layer ILH. The width ILHW2 in the first direction D1 of the bottom surface ILH_U of the upper dielectric layer ILH may be a maximum one of widths in the first direction D1 of the upper dielectric layer ILH. The maximum width ILHW2 in the first direction D1 of the upper dielectric layer ILH may be the same as the minimum width 210W1 in the first direction D1 of the upper semiconductor substrate 210.

Referring back to FIG. 1, a first mold layer MD1 may be formed on the top surface 100a of the lower semiconductor chip 100 so as to be provided on and cover the upper semiconductor chip 200.

According to one or more embodiments, the upper semiconductor chip 200 may be stacked on the lower semiconductor chip 100, and then the planarization process may be performed on the upper semiconductor chip 200. It may thus be possible to minimize a distribution in height of the top surface ILH_U of the upper dielectric layer ILH. When there is a large distribution in height of the top surface ILH_U of the upper dielectric layer ILH in a case that a plurality of upper semiconductor chips 200 are stacked on the lower semiconductor chip 100, a semiconductor package may have therein accumulation of warpage caused by the height distribution of the top surfaces ILH_U of the upper dielectric layers ILH. The warpage may cause the creation of voids between the plurality of upper semiconductor chips 200, and this may reduce in reliability and durability of the semiconductor package. According to one or more embodiments, a planarization process may be performed each time when the upper semiconductor chip 200 is stacked, thus it may be possible to minimize a distribution in height of the top surface ILH_U of the upper dielectric layer ILH and as a result to minimize the creation of voids between the upper semiconductor chips 200. Accordingly, a semiconductor package may improve in reliability and durability.

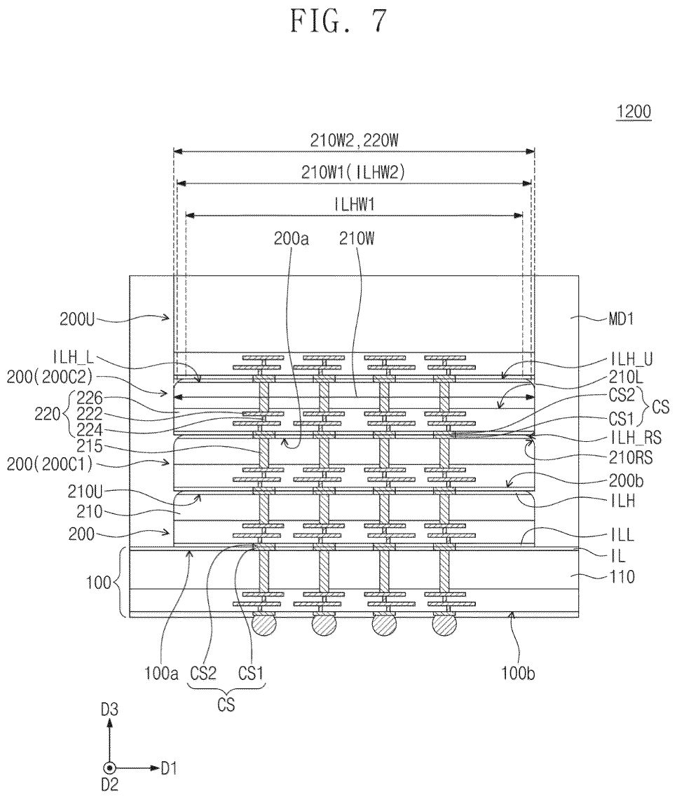

FIG. 7 illustrates a cross-sectional view showing a semiconductor package according to one or more other embodiments. The same explanation as that of the semiconductor package discussed with reference to FIGS. 1 to 3 will be omitted for brevity of description.

A semiconductor package 1200 may include a plurality of upper semiconductor chips 200 that are stacked vertically (e.g., in the third direction D3) on the top surface 100a of the lower semiconductor chip 100. The connection structure CS, discussed with reference to FIGS. 1 to 3, may be disposed between the lower semiconductor chip 100 and a lowermost one of the upper semiconductor chips 200 and between the upper semiconductor chips 200.

Each of the upper semiconductor chips 200 may include an upper semiconductor substrate 210 and an upper circuit layer 220. Each of the upper semiconductor chips 200 may have a top surface 200a and a bottom surface 200b, and the upper circuit layer 220 may be provided on and adjacent to the bottom surface 200b of each of the upper semiconductor chips 200. Adjacent upper semiconductor chips 200 may be stacked to enable the top surface 200a of one of adjacent upper semiconductor chips 200 to face the bottom surface 200b of another of the adjacent upper semiconductor chips 200. The bottom surface 200b of the lowermost upper semiconductor chip 200 may face the top surface 100a of the lower semiconductor chip 100.

Each of the upper semiconductor chips 200 may further include a plurality of upper through vias 215 that penetrate the upper semiconductor substrate 210. According to one or more embodiments, as shown in figures, an uppermost one 200U of the upper semiconductor chips 200 may not include the upper through vias 215. An end of each of the upper through vias 215 may be connected to a corresponding one 222 of the upper wiring patterns 222 and 224 in the upper circuit layer 220, and another end of each of the upper through vias 215 may be connected to the connection structure CS.

The upper semiconductor chips 200 may include a first upper semiconductor chip 200C1 and a second upper semiconductor chip 200C2 that is immediately adjacent to each other. The top surface 200a of the first upper semiconductor chip 200C1 may face the bottom surface 200b of the second upper semiconductor chip 200C2. A lower dielectric layer ILL may be interposed between the first upper semiconductor chip 200C1 and the second upper semiconductor chip 200C2, and an upper dielectric layer ILH may be interposed between the lower dielectric layer ILL and the first upper semiconductor chip 200C1. The upper semiconductor substrate 210 of each of the first and second upper semiconductor chips 200C1 and 200C2 may have a rounded lateral surface 210RS. A width 210W1 in the first direction D1 of a top surface 210U of the upper semiconductor substrate 210 may be less than a width 210W2 in the first direction D1 of a bottom surface 210L of the upper semiconductor substrate 210. A width 210W in the first direction D1 of the upper semiconductor substrate 210 may decrease with increasing distance from the lower semiconductor chip 100 along the direction (e.g., the third direction D3) perpendicular to the top surface 100a of the lower semiconductor chip 100. The first direction D1 may be parallel to the top surface 100a of the lower semiconductor chip 100.

An upper dielectric layer ILH may be disposed on the top surface 200a of each of the upper semiconductor chips 200 and on the upper semiconductor substrate 210. The upper dielectric layer ILH may have a rounded lateral surface ILH_RS. A width ILHW1 in the first direction D1 of a top surface ILH_U of the upper dielectric layer ILH may be less than a width ILHW2 in the first direction D1 of a bottom surface ILH_L of the upper dielectric layer ILH. The width ILHW1 in the first direction D1 of the top surface ILH_U of the upper dielectric layer ILH may be less than the width 210W1 in the first direction D1 of the top surface 210U of the upper semiconductor substrate 210. The width ILHW2 in the first direction D1 of the bottom surface ILH_L of the upper dielectric layer ILH may be the same as the width 210W1 in the first direction D1 of the top surface 210U of the upper semiconductor substrate 210 and less than the width 210W2 in the first direction D1 of the bottom surface 210L of the upper semiconductor substrate 210.

The connection structure CS may penetrate the upper dielectric layer ILH and the lower dielectric layer ILL, and may connect to each other the first and second upper semiconductor chips 200C1 and 200C2. The connection structure CS may include a first connection part CS1 in the upper dielectric layer ILH and a second connection part CS2 in the lower dielectric layer ILL. According to one or more embodiments, the first connection part CS1 may be connected to a corresponding one of the upper through vias 215 in the first upper semiconductor chip 200C1, and the second connection part CS2 may be connected to a corresponding one 224 of the upper wiring patterns 222 and 224 in the upper circuit layer 220 of the second upper semiconductor chip 200C2.

Except for that discussed above, a structure of the semiconductor package 1200 according to the one or more embodiments may be substantially the same as that of the semiconductor package 1000 discussed with reference to FIGS. 1 to 3.

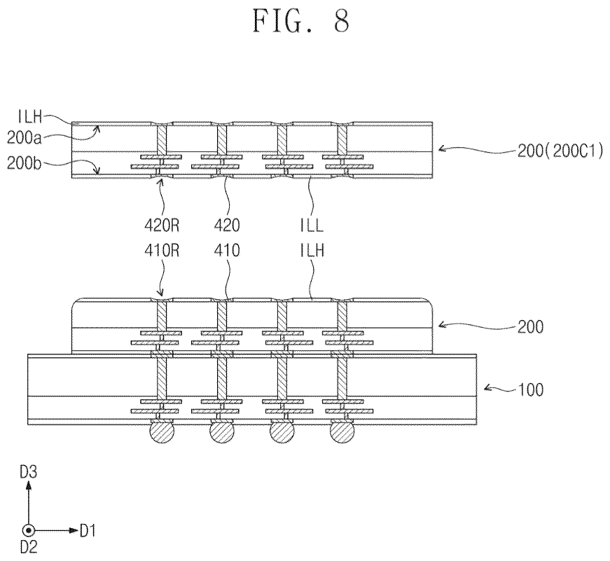

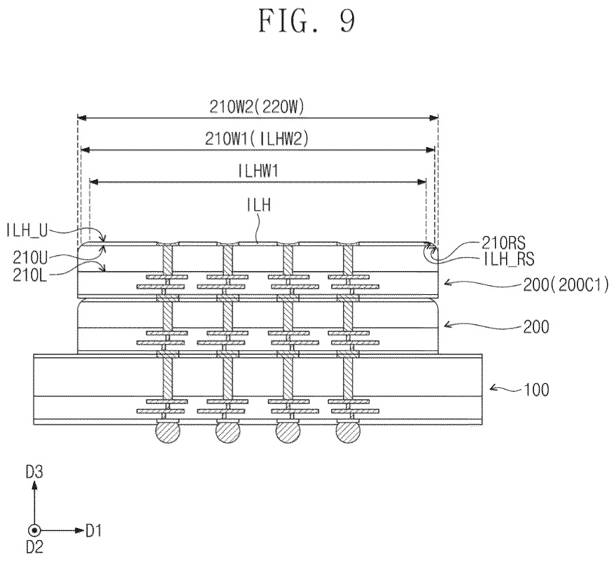

FIGS. 8 and 9 illustrate cross-sectional views showing a method of fabricating a semiconductor package according to one or more embodiments. The same explanation as that of the semiconductor package discussed with reference to FIGS. 1 to 6 will be omitted for brevity of description.

Referring to FIG. 7, a semiconductor package 1200 may include a plurality of upper semiconductor chips 200 that are vertically stacked on the top surface 100a of the lower semiconductor chip 100. The connection structure CS, discussed with reference to FIGS. 4 and 5, may be disposed between the lower semiconductor chip 100 and a lowermost one of the upper semiconductor chips 200 and between the upper semiconductor chips 200.

Referring to FIGS. 7 to 9, a first upper semiconductor chip 200C1 and a second upper semiconductor chip 200C2 may be stacked on the lowermost upper semiconductor chip 200. The lowermost upper semiconductor chip 200, the first upper semiconductor chip 200C1, and the second upper semiconductor chip 200C2 may each have a top surface 200a and a bottom surface 200b that are opposite to each other. As discussed with reference to FIG. 6, the upper semiconductor substrate 210 of the lowermost upper semiconductor chip 200 may have a rounded lateral surface 210RS, and an upper dielectric layer ILH formed on the top surface 200a of the lowermost upper semiconductor chip 200 may have a top surface ILH_U that is planarized by a planarization process. The upper dielectric layer ILH on the top surface 210U of the lowermost upper semiconductor chip 200 may have a lateral surface ILH_RS that is rounded by the planarization process.

Referring back to FIG. 8, the bottom surface 200b of the first upper semiconductor chip 200C1 may be disposed to face the top surface 200a of the lowermost upper semiconductor chip 200. A first connection pad 410 of the lowermost upper semiconductor chip 200 may face a second connection pad 420 of the first upper semiconductor chip 200C1. The upper dielectric layer ILH on the top surface 200a of the lowermost upper semiconductor chip 200 may face and directly contact a lower dielectric layer ILL on the bottom surface 200b of the first upper semiconductor chip 200C1. An annealing process may be performed after direct contact between the first connection pad 410 of the lowermost upper semiconductor chip 200 and the second connection pad 420 of the first upper semiconductor chip 200C1. The annealing process may cause that the first and second connection pads 410 and 420 are directly bonded to form a single structure, which may be a connection structure CS. The dielectric layer IL and the lower dielectric layer ILL may be directly bonded by the annealing process.

Referring to FIG. 9, the first upper semiconductor chip 200C1 may be stacked on the top surface 200a of the lowermost upper semiconductor chip 200, and then a planarization process may be performed to planarize a top surface ILH_U of the upper dielectric layer ILH formed on the top surface 200a of the first upper semiconductor chip 200C1. The planarization process may enable the upper dielectric layer ILH and the upper semiconductor substrate 210 to have rounded lateral surfaces ILH_RS and 210RS, respectively. A width 210W1 in the first direction D1 of the top surface 210U of the upper semiconductor substrate 210 may be less than a width 210W2 in the first direction D1 of the bottom surface 210L of the upper semiconductor substrate 210 included in the first upper semiconductor chip 200C1. A width ILHW1 in the first direction D1 of the top surface ILH_U of the upper dielectric layer ILH may be less than the width 210W1 in the first direction D1 of the top surface 210U of the upper semiconductor substrate 210. The width ILHW1 in the first direction D1 of the top surface ILH_U of the upper dielectric layer ILH may be less than a width 210W2 in the first direction D1 of the bottom surface 210L of the upper semiconductor substrate 210.

According to one or more example embodiments, the upper semiconductor chip 200 may be stacked on the lower semiconductor chip 100, and then the planarization process may be performed on the upper semiconductor chip 200. It may thus be possible to minimize height distribution of the top surface ILH_U of the upper dielectric layer ILH. When there is a large distribution in height of the top surface ILH_U of the upper dielectric layer ILH in a case that a plurality of upper semiconductor chips 200 are stacked on the lower semiconductor chip 100, the semiconductor package 1200 may have therein accumulation of warpage caused by the height distribution of the top surfaces ILH_U of the upper dielectric layers ILH. The warpage may cause the creation of voids between the plurality of upper semiconductor chips 200, and this may reduce in reliability and durability of the semiconductor package 1200. According to one or more embodiments, a planarization process may be performed each time when the upper semiconductor chip 200 is stacked, thus it may be possible to minimize a distribution in height of the top surface ILH_U of the upper dielectric layer ILH and as a result to minimize the creation of voids between the upper semiconductor chips 200. Accordingly, the semiconductor package 1200 may improve in reliability and durability.

Referring back to FIG. 7, the second upper semiconductor chip 200C2 may be stacked on the first upper semiconductor chip 200C1. The bottom surface 200b of the second upper semiconductor chip 200C2 may face the top surface 200a of the first upper semiconductor chip 200C1. The method of stacking the second upper semiconductor chip 200C2 on the top surface 200a of the first upper semiconductor chip 200C1 may be substantially the same as the method of stacking the first upper semiconductor chip 200C1 on the lowermost upper semiconductor chip 200.

According to one or more embodiments, an uppermost one 200U of the plurality of upper semiconductor chips 200 may not include the upper through vias 215, and neither the upper dielectric layer ILH nor the first connection pads 410 may be formed on the top surface 200a of the uppermost upper semiconductor chip 200U. Subsequent processes may be substantially the same as the method of fabricating a semiconductor package discussed with reference to FIGS. 1 to 4.

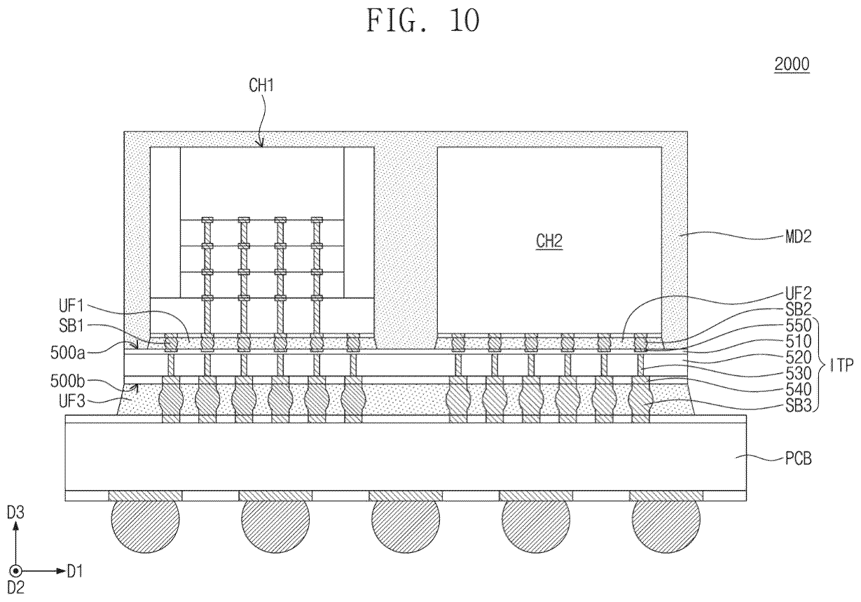

FIG. 10 illustrates a cross-sectional view showing a semiconductor package according to one or more other embodiments. The same explanation as that of the semiconductor package discussed with reference to FIGS. 1 to 3 will be omitted for brevity of description.

Referring to FIG. 10, in a semiconductor package 1000 according to one or more embodiments, an interposer substrate ITP may be disposed on a package substrate PCB. The package substrate PCB may be, for example, a double-sided or multi-layered printed circuit board. A first chip structure CH1 and a second chip structure CH2 may be disposed side-by-side in a first direction D1 on the interposer substrate ITP.

The interposer substrate ITP may include a base substrate 520, a plurality of through electrodes 530 that penetrate the base substrate 520, and a wiring layer 510 on the base substrate 520. The base substrate 520 may be, for example, a silicon substrate. The plurality of through electrodes 530 may be spaced apart horizontally (e.g., in the first direction D1) from each other, and each of the plurality of through electrodes 530 may penetrate the base substrate 520. The plurality of through electrodes 530 may include metal (e.g., copper (Cu)). The wiring layer 510 may include metal patterns electrically connected to the plurality of through electrodes 530. The interposer substrate ITP may have a third surface 500a and a fourth surface 500b that are opposite to each other, and the wiring layer 510 may be provided on and adjacent to the third surface 500a. The fourth surface 500b of the interposer substrate ITP may correspond to one surface of the base substrate 520. Each of the plurality of through electrodes 530 may extend from the wiring layer 510 toward the fourth surface 500b.

First substrate pads 560 may be disposed provided on and adjacent to the third surface 500a of the interposer substrate ITP. The first substrate pads 560 may be spaced apart from each other along a direction (e.g., the first direction D1) parallel to the third surface 500a of the interposer substrate ITP. The first substrate pads 550 may be connected to the metal patterns in the wiring layer 510, and may be electrically connected through the metal patterns to the plurality of through electrodes 530. The first substrate pads 550 may include a conductive material.

Second substrate pads 540 may be disposed on the fourth surface 500b of the interposer substrate ITP. The second substrate pads 540 may be spaced apart from each other along a direction (e.g., the first direction D1) parallel to the fourth surface 500b of the interposer substrate ITP. Each of the plurality of through electrodes 530 may be connected to a corresponding one of the second substrate pads 540. The second substrate pads 540 may include a conductive material.

Third external connection members SB3 may be disposed on the fourth surface 500b of the interposer substrate ITP, and may be correspondingly connected to the second substrate pads 540. The third external connection members SB3 may be correspondingly disposed on the second substrate pads 540.

The first chip structure CH1 may be connected through first external connection members SB1 to the interposer substrate ITP. The first chip structure CH1 may be substantially the same as the semiconductor package 1000 discussed with reference to FIGS. 1 to 3. The first chip structure CH1 may include the connection structure CS discussed with reference to FIGS. 1 to 3.

The second chip structure CH2 may be an application specific integrated circuit (ASIC) or a system-on-chip (SOC). The second chip structure CH2 may be a host or an application processor (AP). Alternatively, the second chip structure CH2 may be a semiconductor chip substantially the same as the first chip structure CH1. The second chip structure CH2 may be connected through second external connection members SB2 to the interposer substrate ITP.

A second mold layer MD2 may be provided on and cover the third surface 500a of the interposer substrate ITP, and may also be provided on and cover the first and second chip structures CH1 and CH2. The second mold layer MD2 may include a dielectric resin, for example, an epoxy molding compound (EMC). The second mold layer MD2 may further include fillers, and the fillers may be dispersed in the dielectric resin. The fillers may include, for example, silicon oxide (SiO₂).

The interposer substrate ITP may be bonded through the third external connection members SB3 to the package substrate PCB. Fourth external connection members SB4 may be bonded to a bottom end of the package substrate PCB. The external connection members SB1 to SB4 may include at least one of, for example, copper bumps, copper pillars, and solder balls. Underfills UF1, UF2, and UF3 may be respectively provided between the first chip structure CH1 and the interposer substrate ITP, between the second chip structure CH2 and the interposer substrate ITP, and between the interposer substrate ITP and the package substrate PCB. The underfills UF1, UF2, and UF3 may be formed by dispensing and curing processes. The underfills UF1, UF2, and UF3 may include an epoxy resin, and may protect the external connection members SB1, SB2, and SB3.

In a semiconductor package according to one or more embodiments, a planarization process may be performed when upper semiconductor chips are stacked on a top surface of a lower semiconductor chip. The planarization process may enable an upper semiconductor substrate of the upper semiconductor chip to have a rounded lateral surface and an upper dielectric layer on a top surface of the upper semiconductor chip to have a rounded lateral surface. The planarization process may prevent warpage occurring when other semiconductor chip is stacked on the upper semiconductor chip. In addition, the planarization process may cause the absence of voids caused by warpage occurring when other upper semiconductor chip is stacked on the upper semiconductor chip. Accordingly, the semiconductor package may improve in durability and reliability.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package, comprising:
a lower semiconductor chip comprising a top surface and a bottom surface that are opposite to each other;
an upper semiconductor chip on the top surface of the lower semiconductor chip and comprising a bottom surface and a top surface that are opposite to each other;
a dielectric layer between the top surface of the lower semiconductor chip and the bottom surface of the upper semiconductor chip;
a lower dielectric layer between the dielectric layer and the bottom surface of the upper semiconductor chip;
an upper dielectric layer on the top surface of the upper semiconductor chip; and
a connection structure that penetrates the dielectric layer and the lower dielectric layer, the connection structure being connected to the lower semiconductor chip and the upper semiconductor chip,
wherein a width of the bottom surface of the upper semiconductor chip is greater than a width of the upper dielectric layer in a first direction, and
wherein the first direction is parallel to the top surface of the lower semiconductor chip.

2. The semiconductor package of claim 1, wherein the upper semiconductor chip includes:
an upper circuit layer on the bottom surface of the upper semiconductor chip; and
an upper semiconductor substrate on the top surface of the upper semiconductor chip,
wherein a top surface of the upper semiconductor substrate corresponds to the top surface of the upper semiconductor chip,
wherein a bottom surface of the upper semiconductor substrate is on the upper circuit layer, and
wherein a width of the top surface of the upper semiconductor substrate is less than a width of the bottom surface of the upper semiconductor substrate in the first direction.

3. The semiconductor package of claim 2, wherein a lateral surface of the upper semiconductor substrate is rounded.

4. The semiconductor package of claim 1, wherein the dielectric layer contacts the lower dielectric layer.

5. The semiconductor package of claim 1, wherein the upper dielectric layer has a bottom surface and a top surface that are opposite to each other,
wherein the bottom surface of the upper dielectric layer contacts the top surface of the upper semiconductor chip, and
wherein a lateral surface of the upper dielectric layer is rounded.

6. The semiconductor package of claim 5, wherein the width of the upper dielectric layer is less than a width of the lower dielectric layer in the first direction.

7. The semiconductor package of claim 5, wherein a width of the upper semiconductor chip in the first direction decreases as a distance from the lower semiconductor chip along a direction perpendicular to the top surface of the lower semiconductor chip increases.

8. The semiconductor package of claim 1, wherein the connection structure comprises:
a first connection part in the dielectric layer; and
a second connection part in the lower dielectric layer.

9. The semiconductor package of claim 8, wherein the first connection part and the second connection part comprise same material.

10. The semiconductor package of claim 8, wherein the lower semiconductor chip comprises:
a lower circuit layer; and
a lower through via that penetrates the lower semiconductor chip and is connected to the lower circuit layer,
wherein the first connection part is connected to the lower through via.

11. The semiconductor package of claim 10, wherein the upper semiconductor chip comprises:
an upper circuit layer; and
an upper through via that penetrates the upper semiconductor chip and is connected to the upper circuit layer,
wherein the second connection part is connected to the upper through via.

12. A semiconductor package, comprising:
a lower semiconductor chip comprising a top surface and a bottom surface that are opposite to each other;
a plurality of upper semiconductor chips on the top surface of the lower semiconductor chip and stacked in a direction perpendicular to the top surface of the lower semiconductor chip, the plurality of upper semiconductor chips comprising a first upper semiconductor chip and a second upper semiconductor chip adjacent to each other;
a lower dielectric layer between the first upper semiconductor chip and the second upper semiconductor chip;
an upper dielectric layer between the lower dielectric layer and the first upper semiconductor chip; and
a connection structure that penetrates the upper dielectric layer and the lower dielectric layer, the connection structure being connected to the first upper semiconductor chip and the second upper semiconductor chip,
wherein a width of the upper dielectric layer is less than a width of the lower dielectric layer in a first direction,
wherein the first direction is parallel to the top surface of the lower semiconductor chip.

13. The semiconductor package of claim 12, wherein the lower dielectric layer contacts the upper dielectric layer.

14. The semiconductor package of claim 12, wherein each of the first upper semiconductor chip and the second upper semiconductor chip has a top surface and a bottom surface that are opposite to each other,
wherein the top surface of the first upper semiconductor chip faces the bottom surface of the second upper semiconductor chip,
wherein the lower dielectric layer and the upper dielectric layer are between the top surface of the first upper semiconductor chip and the second upper semiconductor chip, and
wherein each of the first upper semiconductor chip and the second upper semiconductor chip comprises:
an upper semiconductor substrate on the top surface of a corresponding one of the first upper semiconductor chip and the second upper semiconductor chip; and
an upper circuit layer on the bottom surface of a corresponding one of the first upper semiconductor chip and the second upper semiconductor chip,
a top surface of the upper semiconductor substrate corresponds to the top surface of a corresponding one of the first upper semiconductor chip and the second upper semiconductor chip,
a bottom surface of the upper semiconductor substrate is on the upper circuit layer, and
a width of the top surface of the upper semiconductor substrate is less than a width of the bottom surface of the upper semiconductor substrate in the first direction.

15. The semiconductor package of claim 14, wherein a width of a top surface of the upper dielectric layer is less than the width of the top surface of the upper semiconductor substrate in the first direction.

16. The semiconductor package of claim 14, wherein a width of a top surface of the upper dielectric layer is less than the width of the bottom surface of the upper semiconductor substrate in the first direction.

17. A semiconductor package, comprising:
a lower semiconductor chip comprising a top surface and a bottom surface that are opposite to each other;
an upper semiconductor chip on the top surface of the lower semiconductor chip and having a bottom surface and a top surface that are opposite to each other;
a dielectric layer between the top surface of the lower semiconductor chip and the bottom surface of the upper semiconductor chip;
a lower dielectric layer between the dielectric layer and the bottom surface of the upper semiconductor chip;
an upper dielectric layer on the top surface of the upper semiconductor chip; and
a connection structure that penetrates the dielectric layer and the lower dielectric layer, the connection structure being connected to the lower semiconductor chip and the upper semiconductor chip,
wherein a lateral surface of the upper dielectric layer is rounded,
wherein a width of the upper dielectric layer in a first direction decreases as a distance from the lower semiconductor chip along a direction perpendicular to the top surface of the lower semiconductor chip increases, and
wherein the first direction is parallel to the top surface of the lower semiconductor chip.

18. The semiconductor package of claim 17, wherein the upper semiconductor chip comprises:
an upper circuit layer on the bottom surface of the upper semiconductor chip; and
an upper semiconductor substrate on the top surface of the upper semiconductor chip,
wherein a top surface of the upper semiconductor substrate corresponds to the top surface of the upper semiconductor chip,
wherein a bottom surface of the upper semiconductor substrate is on the upper circuit layer, and
wherein a width of the top surface of the upper semiconductor substrate is less than a width of the bottom surface of the upper semiconductor substrate in the first direction.

19. The semiconductor package of claim 18, wherein a lateral surface of the upper semiconductor substrate is rounded, and
wherein the width of the upper semiconductor substrate is greater than the width of the upper dielectric layer in the first direction.

20. The semiconductor package of claim 18, wherein a bottom surface of the upper dielectric layer contacts the top surface of the upper semiconductor substrate, and
wherein a width of the bottom surface of the upper dielectric layer is equal to the width of the top surface of the upper semiconductor substrate in the first direction.
